(19) United States
(12) Patent Application Publication
(10) Pub. No.: US 2022/0268520 A1
(43) Pub. Date: Aug. 25, 2022

(54) VERTICAL FURNACE REACTOR ASSEMBLY, METHOD OF ALIGNING ANNULAR FLANGE UNITS, AND USE

(71) Applicant: ASM IP Holding B.V., Almere (NL)

(72) Inventors: Theodorus G.M. Oosterlaken, Oudewater (NL); Lucian C. Jdira, Nieuw Vennep (NL); Christianus G.M. de Ridder, Hoogland (NL)

(21) Appl. No.: 17/668,614

(22) Filed: Feb. 10, 2022

Related U.S. Application Data
(60) Provisional application No. 63/149,465, filed on Feb. 15, 2021.

(51) Int. Cl. F27B 1/14; F27D 1/14

(52) U.S. Cl. CPC F27B 1/14; F27D 1/145; F27B 17/0025

(57) ABSTRACT

Vertical furnace reactor assembly, comprising: a reactor housing defining a processing chamber configured for processing substrates therein, the processing chamber having an opening for moving substrates into and out of the processing chamber along a main loading axis, the opening being surrounded by a stack of annular flange units including at least two of a housing flange, a gas divided ring unit, a liner suspension ring unit, a scavenger ring unit and a clamp ring unit, wherein at least two of the annular flange units are provided with mutually cooperating centering structures for centering the respective at least two flange units with respect to each other, wherein the mutually cooperating centering structures comprise a plurality of slots and a corresponding plurality of pins, wherein the slots each extend along a respective main slot axis, wherein the slot axes are directed to mutually intersect centrally with respect to the stack.

### CROSS-REFERENCE TO RELATED APPLICATIONS

This application claims priority to U.S. Provisional Patent Application Ser. No. 63/149,465 filed Feb. 15, 2021 titled VERTICAL FURNACE REACTOR ASSEMBLY, METHOD OF ALIGNING ANNULAR FLANGE UNITS, AND USE, the disclosure of which is hereby incorporated by reference in its entirety.

### FIELD

The invention relates to a vertical furnace reactor assembly for processing substrates, a method of aligning annular flange units of such a reactor assembly, and use of such a reactor assembly.

### BACKGROUND

A known vertical furnace reactor assembly for processing substrates comprises a reactor housing defining a processing chamber configured for processing substrates therein, the processing chamber having an opening for moving substrates into and out of the processing chamber along a main loading axis, the opening being surrounded by a stack of annular flange units. Such annular flange units may include a housing flange, a gas divided ring unit, a liner suspension ring unit, a scavenger ring unit and/or a clamp ring unit.

To achieve good operational performance of the reactor, the annular flange units need to be positioned in accurate alignment with respect to each other. Achieving such alignment in a known reactor assembly can be cumbersome and time consuming and requires highly skilled handling.

### SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An object of the invention may be to provide a vertical furnace reactor assembly for processing substrates, wherein proper mutual alignment of annular flange units can be achieved more easily and/or quickly. An object may be to provide such a reactor assembly which may be less prone to misalignment between annular flange units.

To that end, an aspect of the invention may provide a vertical furnace reactor assembly for processing substrates. The reactor assembly may comprise a reactor housing defining a processing chamber which may be configured for processing substrates therein. The processing chamber may have an opening for moving substrates into and out of the processing chamber along a main loading axis. The opening may be surrounded by a stack of annular flange units including at least two of a housing flange, a gas divided ring unit, a liner suspension ring unit, a scavenger ring unit and a clamp ring unit.

At least two of the annular flange units may be provided with mutually cooperating centering structures for centering the respective at least two flange units with respect to each other. The mutually cooperating centering structures may comprise a plurality of slots and a corresponding plurality of pins. The slots may each extend along a respective main slot axis. The slot axes may be directed to mutually intersect centrally with respect to the stack of annular flange units.

The slots may each be configured to receive a respective one of the pins therein in a direction substantially parallel to the main loading axis such that the received pin may be movable in the slot along the respective main slot axis and substantially immovable in the slot along a direction perpendicular to the main slot axis and the main loading axis.

Preferably, said direction perpendicular to the main slot axis and the main loading axis may at least substantially correspond to a circumferential direction of the annular flange units and/or of the opening.

Such mutually cooperating centering structures may enable relatively easy and quick mutual alignment among respective annular flange units, wherein a risk of unintentional misalignment may be reduced.

When the flange units are positioned with respect to each other, the pins may be inserted in the slots, in particular substantially along the main loading axis. The receiving slots limit pin movement in such a way, that the pins may for example be inserted conveniently one by one, while an automatic centering behavior may be achieved during said positioning.

A further aspect may provide a method of aligning annular flange units of a vertical furnace reactor assembly with respect to each other in a stack. The method may comprise:

providing a vertical furnace reactor assembly as described herein; and

causing pins of the plurality of pins to be inserted into corresponding slots of the plurality of slots, thereby centering the at least two annular flange units with respect to each other.

Such a method may provide above mentioned advantages.

A further aspect may provide a use of a vertical furnace reactor as described herein for processing substrates therein.

Such a use may provide above mentioned advantages.

For purposes of summarizing the invention and the advantages achieved over the prior art, certain objects and advantages of the invention have been described herein above. Of course, it may be to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

Various embodiments are claimed in the dependent claims, which will be further elucidated with reference to an example shown in the figures. The embodiments may be combined or may be applied separate from each other.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 shows a cross sectional side view of an exemplary vertical furnace reactor assembly according to a first embodiment;

FIG. 2 shows a cross sectional side view of an exemplary vertical furnace reactor assembly according to a second embodiment;

FIG. 3 shows a top view of exemplary mutually cooperating centering structures;

FIG. 4 shows an isometric view of an exemplary stack of annular flange units;

FIG. 5 shows an isometric view of an exemplary scavenger ring;

FIG. 6 shows an isometric view of a further exemplary scavenger ring; and

FIG. 7 shows an isometric view of an exemplary clamp ring.

### DETAILED DESCRIPTION

In this application similar or corresponding features are denoted by similar or corresponding reference signs. The description of the various embodiments is not limited to the example shown in the figures and the reference numbers used in the detailed description and the claims are not intended to limit the description of the embodiments, but are included to elucidate the embodiments

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below. The illustrations presented herein are not meant to be actual views of any particular material, structure, or device, but are merely idealized representations that are used to describe embodiments of the disclosure.

As used herein, the term “wafer” may refer to any underlying material or materials that may be used, or upon which, a device, a circuit, or a film may be formed.

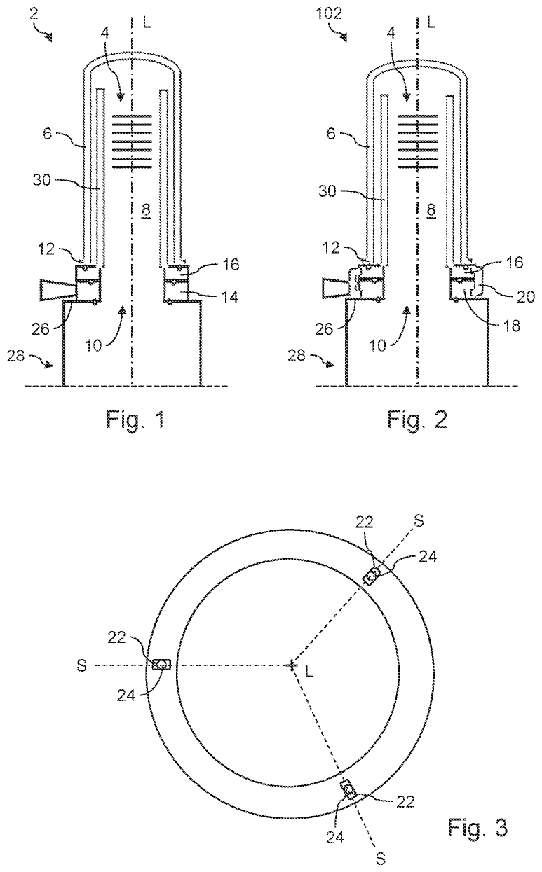

FIGS. 1 and 2 show examples of a vertical furnace reactor assembly 2; 102 which can be used for processing substrates 4 therein.

The reactor assembly 2; 102 may comprise a reactor housing 6 defining a processing chamber 8 which may be configured for processing substrates 4 therein. The processing chamber 8 may have an opening 10, here at a bottom side of the chamber 8, for moving substrates 4 into and out of the processing chamber 8 along a main loading axis L. The opening 10 may be surrounded by a stack of annular flange units. The annular flange units may include at least two of a housing flange 12, 26, a gas divided ring unit 14, a liner suspension ring unit 16, a scavenger ring unit 18 and a clamp ring unit 20.

In the example of FIG. 1, the stack shown therein includes a housing flange 12 of the reactor housing 6, a gas divided ring unit 14, a liner suspension ring unit 16, and a further housing flange 26. Since the housing 6 defines the processing chamber 8, the housing flange 12 may also be called processing chamber flange 12. In the example of FIG. 2, the stack shown therein includes a housing flange 12 of the reactor housing 6, a liner suspension ring unit 16, a scavenger ring unit 18, a clamp ring unit 20, and a further housing flange 26. One or more (further) clamp ring units (not indicated in the drawings) may be provided in any one or more of the shown examples, in particular between the liner suspension ring unit 16 and the housing flange 12, and/or between the scavenger ring unit 18 and the liner suspension ring unit 16.

The further housing flange 26 may be associated with a wafer boat handling device 28 which may be configured to move batches of substrates 4 into and out of the chamber 8 for processing therein. The liner suspension ring unit 16 may be associated with a liner 30 of the reactor assembly 2.

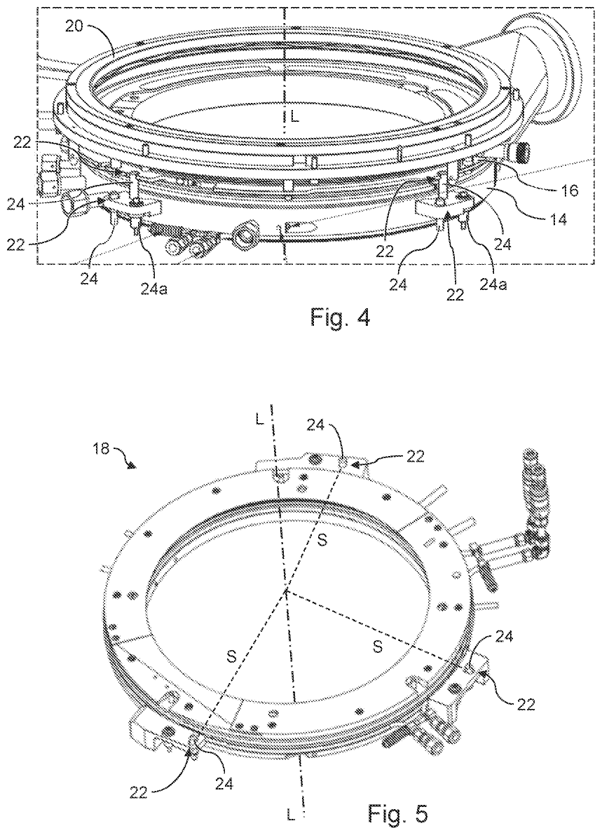

In the example of FIG. 4, the stack shown therein includes a clamp ring unit 20, a liner suspension unit 16 and a gas divided ring unit 14. In the example of FIG. 4, a housing flange which is not shown may be positioned below the gas divided ring unit 14. Pins 24 of said housing flange are nevertheless shown, as will be explained further.

It will be appreciated that the shown stack compositions merely represent examples and that such stacks may be composed differently, for example from different sets of annular flange units, in different orders, and/or with one or more additional annular flange units.

As shown for example in FIG. 2, flange units may be stacked such that one flange unit partially or fully surrounds another flange unit.

At least two of the annular flange units 12, 14, 16, 18, 20, 26 may be provided with mutually cooperating centering structures 22, 24 (see e.g. FIG. 3, not explicitly shown in FIGS. 1 and 2) for centering the respective at least two flange units 12, 14, 16, 18, 20, 26 with respect to each other.

The mutually cooperating centering structures 22, 24 may comprise a plurality of slots 22 and a corresponding plurality of pins 24. The slots 22 may each extend along a respective main slot axis S, wherein the slot axes S may be directed to mutually intersect centrally with respect to the stack of annular flange units 12, 14, 16, 18, 20, 26. The slot axes S may intersect with the main loading axis L, i.e. at a center line of the stack and/or the reactor assembly 2; 102. Alternatively, some or all of the slot axes S may intersect with at least one other of the slot axes S at a small distance from the main loading axis L, in particular a small distance compared to a distance between said intersection point and the respective slots 22.

The slots 22 may each be configured to receive a respective one of the pins 24 therein in a direction substantially parallel to the main loading axis L such that the received pin 24 may be movable in the slot 22 along the respective main slot axis S and may be substantially immovable in the slot 22 along a direction perpendicular to the main slot axis S and the main loading axis L.

In the example of FIG. 3, the slots 22 are closed at both of their axial ends. Alternatively, for example, one or more of the slots 22 may be open ended, for example at one or two of the axial ends. An example thereof can be seen in FIG. 4.

FIG. 4 shows several sets of mutually cooperating centering structures, in particular slots 22 and pins 24, in a stack of annular flange units 20, 16, 14. Pins 24 of the housing flange (itself not shown) below the gas divided ring unit 14 are shown as received in slots 22 of the gas divided ring unit 14. Pins 24 of the gas divided ring unit 14 are shown as received in slots 22 of the liner suspension ring unit 16.

FIG. 5 shows pins 24 of a housing flange (itself not shown) which are received in an exemplary scavenger ring unit 18.

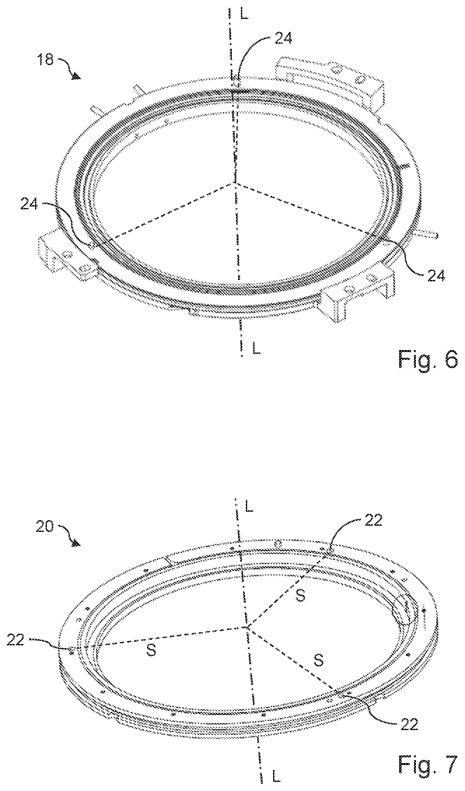

FIG. 6 shows an exemplary scavenger ring unit 18 with pins 24 which may be received in slots 22 of an exemplary clamp ring unit 20 shown in FIG. 7.

In an embodiment, the plurality of slots 22 may comprise at least three slots 22 and the corresponding number of pins 24 correspondingly may comprise at least three pins 24. It will be appreciated that the numbers of slots 22 and pins 24 are here defined per centering structure, i.e. for example per annular flange unit.

Thus, when for example two annular flange units are provided with mutually cooperating centering structures, one of said flange units may be provided with at least three slots 22 while another of said flange units may be provided with at least three pins 24. In a less preferred yet possible alternative, one of said flange units may be provided with e.g. two slots 22 and one pin 24, while another of said flange units may be provided with one slot 22 and two pins 24. It will be appreciated that many further variations and combinations may thus be possible.

By providing at least three slots 22 and at least three pins 24, good centering behavior may be obtained while positioning the pins 24 in the slots 22 may be relatively easy.

In an embodiment, the corresponding pluralities of slots 22 and pins 24 may be substantially evenly distributed along respective circumferences of the respective annular flange units 12, 14, 16, 18, 20, 26.

The centering behavior may be further improved thereby.

In an embodiment, the respective main slot directions S of each pair of slots 22 of the at least three slots 22 may mutually include an angle of about 120 degrees in a plane which may be transversal to the main loading axis L. Alternatively, one or more pairs of slots may include a different angle, for example substantially larger or smaller than 120 degrees.

In an embodiment, the pins 24 may each extend along a main pin direction which may be substantially parallel to the main loading axis L.

The pins 24 may thus be inserted into the slots 22 in the direction of the main loading axis L, while movement of the received pins 24 in one or more directions transverse to said main loading axis L may be limited by the slots 22.

In an embodiment, the mutually cooperating centering structures 22, 24 may be configured to provide at least one of a kinematic coupling and a non-kinematic coupling between the respective annular flange units 12, 14, 16; 18, 20, 26.

In an embodiment, the stack of annular flange units 12, 14, 16, 26; 12, 18, 20, 26 may comprise at least three, preferably at least four, annular flange units 12, 14, 16, 26; 12, 18, 20, 26.

In an embodiment, the reactor assembly 2; 102 may comprise a plurality of, e.g. three, leveling pins 24a (see FIG. 4) which may be configured to adjust a mutual leveling of respective ones of the annular flange units 12, 14, 16, 18, 20, 26, in particular including the gas divided ring unit 14.

In an embodiment, a joint circumferential shape of the annular flange units 12, 14, 16; 18, 20, 26 may be a circular shape having its center at the main loading axis L.

Relatively strong flange units can thus be provided, in particular with a relatively large opening therein relative to their circumference. Such a circular flange shape may be matched to a circular shape of the opening 10 and/or the reactor housing 6.

With reference to the drawings as illustration, a method of aligning annular flange units 12, 14, 16, 18, 20, 26 of a vertical furnace reactor assembly 2; 102 with respect to each other in a stack may comprise:

providing a vertical furnace reactor assembly 2 as described herein; and

causing pins 24 of the plurality of pins 24 to be inserted into corresponding slots 22 of the plurality of slots 22, thereby centering the at least two annular flange units 12, 14, 16, 18, 20, 26 with respect to each other.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims.

For example, a stack of annular flange units may comprise one or more annular flange units which do not comprise pins and/or slots for centering with respect to another flange unit. Further examples have been provided throughout the description.

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this description are not necessarily all referring to the same embodiment.

Furthermore, it is noted that particular features, structures, or characteristics of one or more of the various embodiments which are described above may be used implemented independently from one another and may be combined in any suitable manner to form new, not explicitly described embodiments. The reference numbers used in the detailed description and the claims do not limit the description of the embodiments, nor do they limit the claims. The reference numbers are solely used to clarify.

1. A vertical furnace reactor assembly for processing substrates, comprising a reactor housing defining a processing chamber configured for processing substrates therein, the processing chamber having an opening for moving substrates into and out of the processing chamber along a main loading axis, the opening being surrounded by a stack of annular flange units including at least two of a housing flange, a gas divided ring unit, a liner suspension ring unit, a scavenger ring unit and a clamp ring unit,
wherein at least two of the annular flange units are provided with mutually cooperating centering structures for centering the respective at least two flange units with respect to each other,
wherein the mutually cooperating centering structures comprise a plurality of slots and a corresponding plurality of pins, wherein the slots each extend along a respective main slot axis, wherein the slot axes are directed to mutually intersect centrally with respect to the stack of annular flange units,
wherein the slots are each configured to receive a respective one of the pins therein in a direction substantially parallel to the main loading axis such that the received pin is movable in the slot along the respective main slot axis and substantially immovable in the slot along a direction perpendicular to the main slot axis and the main loading axis.

2. The reactor assembly according to claim 1, wherein the plurality of slots comprises at least three slots and the corresponding number of pins correspondingly comprises at least three pins.

3. The reactor assembly according to claim 2, wherein the corresponding pluralities of slots and pins are substantially evenly distributed along respective circumferences of the respective annular flange units.

4. The reactor assembly according to claim 3, wherein respective main slot directions of each pair of slots of the at least three slots mutually include an angle of about 120 degrees in a plane which is transversal to the main loading axis.

5. The reactor assembly according to claim 1, wherein the pins each extend along a main pin direction which is substantially parallel to the main loading axis.

6. The reactor assembly according to claim 1, wherein the mutually cooperating centering structures are configured to provide at least one of a kinematic coupling and a non-kinematic coupling between the respective annular flange units.

7. The reactor assembly according to claim 1, wherein the stack of annular flange units comprises at least three, preferably at least four, annular flange units.

8. The reactor assembly according to claim 1, further comprising a plurality of leveling pins which are configured to adjust a mutual leveling of respective ones of the annular flange units.

9. The reactor assembly according to claim 1, wherein a joint circumferential shape of the annular flange units is a circular shape having its center at the main loading axis.

10. A method of aligning annular flange units of a vertical furnace reactor assembly with respect to each other in a stack, comprising:
providing a vertical furnace reactor assembly according claim 1; and
causing pins of the plurality of pins to be inserted into corresponding slots of the plurality of slots, thereby centering the at least two annular flange units with respect to each other.

11. Use of a vertical furnace reactor assembly according claim 1 for processing substrates therein.
